(19) United States
(12) Patent Application Publication
(10) Pub. No.: US 2018/0047354 A9
(43) Pub. Date: Feb. 15, 2018

(54) SHIFT REGISTER UNIT AND DRIVING METHOD THEREOF, GATE DRIVING CIRCUIT AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Silin Feng, Beijing (CN); Wei Xue, Beijing (CN); Zhifu Dong, Beijing (CN)

(21) Appl. No.: 15/098,832

(22) Filed: Apr. 14, 2016

(30) Foreign Application Priority Data
Jul. 23, 2015 (CN) 201510444344.6

(51) Int. Cl. G09G 3/36; G11C 19/28

(52) U.S. Cl. CPC G09G 3/3648; G11C 19/28; G09G 2310/0283; G09G 2310/0286; G09G 2310/0289

(57) ABSTRACT

A shift register unit includes input, output, restoration, reset, reset reinforce, reset reinforce control, and energy storage modules. The input, output, restoration and energy storage modules are connected to a first node. The output module is adapted to output a shift signal at a first electrical level when the voltage at the first node is at the first electrical level. The reset module is connected to the output module, and the reset module is adapted to set the voltage at the output module to a second electrical level. Both the reset reinforce and reset reinforce control modules are connected to a second node, and the reset reinforce control module includes a first and a second transistor. A channel width to length ratio of the first transistor is greater than that of the second transistor. Switch states of the first and second transistors control the voltage at the second node.

### CROSS REFERENCE TO RELATED APPLICATIONS

This application claims the benefit of Chinese patent application No. 201510444344.6 filed Jul. 23, 2015, the entire content of which is incorporated by reference herein.

### BACKGROUND

The present invention relates to a shift register unit and drive method thereof, a gate drive circuit and a display device.

With the continuous development of liquid crystal displays, high resolution and narrow borders become the trend of the development of liquid crystal displays, and the application of gate shift registers in display panels is one way to achieve narrow borders and high resolution.

TFT-LCD (Thin Film Transistor-Liquid Crystal Display) drivers include a gate drive circuit and a data drive circuit, while the gate drive circuit includes a multi-stage shift register unit and signal lines connecting the respective shift register units, each stage shift register unit being connected with at least a gate line and scanning drive pixel TFT line by line through an output signal of the shift register unit.

After a shift register unit outputs a shift pulse, it is typically required to reset the output terminal of the shift register unit and conduct multiple reinforce resets after this reset. In order to achieve reinforce resets, it is required to design a reinforce reset control module for controlling the reinforce resets. Reinforce reset control modules typically require a large number of transistors, which is not conducive to narrowing borders of the display device.

### BRIEF DESCRIPTION

In an aspect, a shift register unit includes an input module, an output module, a restoration module, a reset module, a reset reinforce module, a reset reinforce control module and an energy storage module. The input module, the output module, the restoration module, and the energy storage module are connected to a first node. The output module includes an output terminal adapted to output a shift signal at a first electrical level via the output terminal of the output module when the voltage at the first node is at the first electrical level. The reset module is connected to the output terminal of the output module and is adapted to set the voltage at the output terminal of the output module to a second electrical level. Both the reset reinforce module and the reset reinforce control module are connected to a second node, the reset reinforce module is adapted to set the voltage at the output terminal of the output module to the second electrical level when the second node reaches a start electrical level of the reset reinforce module, and the second electrical level is opposite to the first electrical level. The reset reinforce control module includes a first transistor and a second transistor, and a channel width to length ratio of the first transistor is greater than a channel width to length ratio of the second transistor. By controlling switch states of the first transistor and of the second transistor, control of the voltage at the second node is achieved.

In some embodiments, the reset reinforce control module also has a first input terminal, a second input terminal and a third input terminal. The first transistor has its gate connected to the output terminal of the output module, its source connected to the second node and its drain connected to the first input terminal, and is turned on when the output terminal of the output module is at the first electrical level. The second transistor has its drain connected to the second node, its gate connected to the second input terminal, and its source connected to the third input terminal.

In some embodiments, the second input terminal and the third input terminal are the same input terminal, and the start electrical level of the reset reinforce module is the same as the start electrical level of the second transistor.

In further embodiments, the reset reinforce module includes a third transistor, the third transistor having its source connected to the output terminal of the output module, its gate connected to the second node and its drain connected to the first input terminal. The start electrical level of the third transistor is at the first electrical level.

In still further embodiments, the output module includes a fourth transistor, the fourth transistor having its source connected to the third input terminal, its drain connected to the output terminal of the output module and its gate connected to the first node. The start electrical level of the fourth transistor is the first electrical level.

In additional embodiments, the input module includes a fifth transistor and has a fourth input terminal and a fifth input terminal, the fifth transistor having its source connected to the fourth input terminal, its gate connected to the fifth input terminal and its drain connected to the first node.

In some embodiments, the restoration module includes a sixth transistor and has a sixth input terminal and a seventh input terminal, the sixth transistor having its source connected to the first node, its gate connected to the seventh input terminal and its drain connected to the sixth input terminal.

Both the start electrical levels of the fifth transistor and of the sixth transistor are the same as the first electrical level.

In additional embodiments, the reset module includes a seventh transistor, the seventh transistor having its gate connected to the seventh input terminal, its source connected to the output terminal of the output module and its drain connected to the first input terminal. The start electrical level of the seventh transistor is the same as the first electrical level.

In further embodiments, the energy storage module is a capacitor, the capacitor having a first terminal connected to the first node and a second terminal connected to the output terminal of the output module.

In some embodiments, each of the transistors is an N-type transistor.

In some embodiments, the width to length ratio of the first transistor is 4-6 times the width to length ratio of the second transistor.

In a second aspect, a gate drive circuit includes a plurality of cascaded shift register units, the shift register units being shift register units of any of the preceding.

In a third aspect, a method of driving the shift register unit of any of the preceding includes controlling, in response to a shift pulse output at the first electrical level by the output module, switch states of the first transistor and of the second transistor so that the voltage at the second node does not reach the start electrical level of the reset reinforce module, and controlling, in response to the voltage at the output terminal of the output module being set to the second electrical level by the reset module, switch states of the first transistor and of the second transistor so that the voltage at the second node reaches the start electrical level of the reset reinforce module.

In some embodiments, the reset reinforce control module has a first input terminal, a second input terminal and a third input terminal.

In some embodiments, controlling switch states of the first transistor and of the second transistor so that the voltage at the second node does not reach the start electrical level of the reset reinforce module includes applying voltage at the first input terminal that turns the reset reinforce module off

In some embodiments, controlling switch states of the first transistor and of the second transistor so that the voltage at the second node reaches the start electrical level of the reset reinforce module includes applying a signal at the second input terminal to turn the second transistor on and applying voltage at the third input terminal that starts the reset reinforce module.

In a fourth aspect, a display device includes the above gate drive circuit.

In the shift register unit provided in the embodiments described herein, two transistors can achieve the function of the reset reinforce control module of the typical shift register unit. Compared to typical shift register units, transistors used may be reduced, thereby being able to occupy less area of the border region and helping narrow borders of the display device.

### BRIEF DESCRIPTION OF THE DRAWINGS

FIG. 1 is a schematic circuit structure diagram of a prior art shift register unit;

FIG. 2 is a timing diagram of several key signals when the shift register unit in FIG. 1 drives;

FIG. 3 is a schematic structure diagram of a shift register unit provided by an exemplary embodiment;

FIG. 4 is a schematic circuit structure diagram of a shift register unit provided by an exemplary embodiment;

FIG. 5 is a timing diagram of several key signals when the shift register unit in FIG. 4 drives;

FIG. 6 is a schematic circuit structure diagram comprising a gate drive circuit of the shift register unit in FIG. 4.

### DETAILED DESCRIPTION

To make the present disclosure more clear, example embodiments of the disclosure will be described below in detail in combination with the accompanying drawings. The embodiments described are merely part of, instead of all the possible embodiments. Based on the embodiments described herein, other embodiments may be obtained by those of ordinary skill in the art without creative efforts, and those other embodiments also will fall within the scope of the present disclosure.

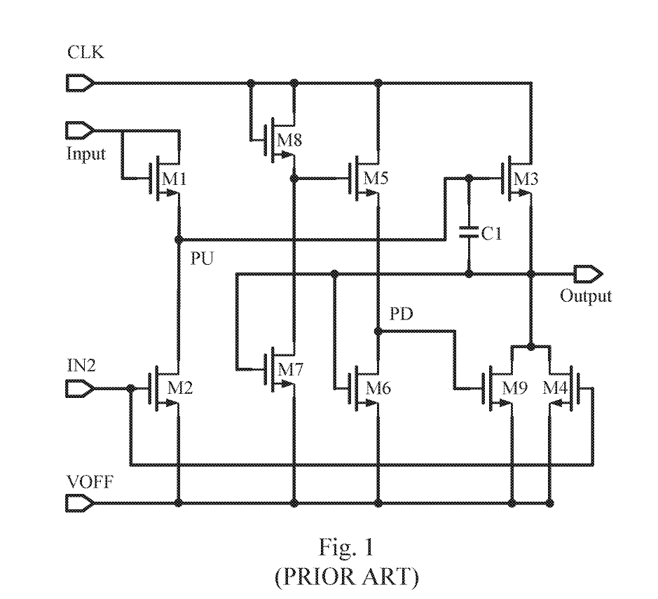

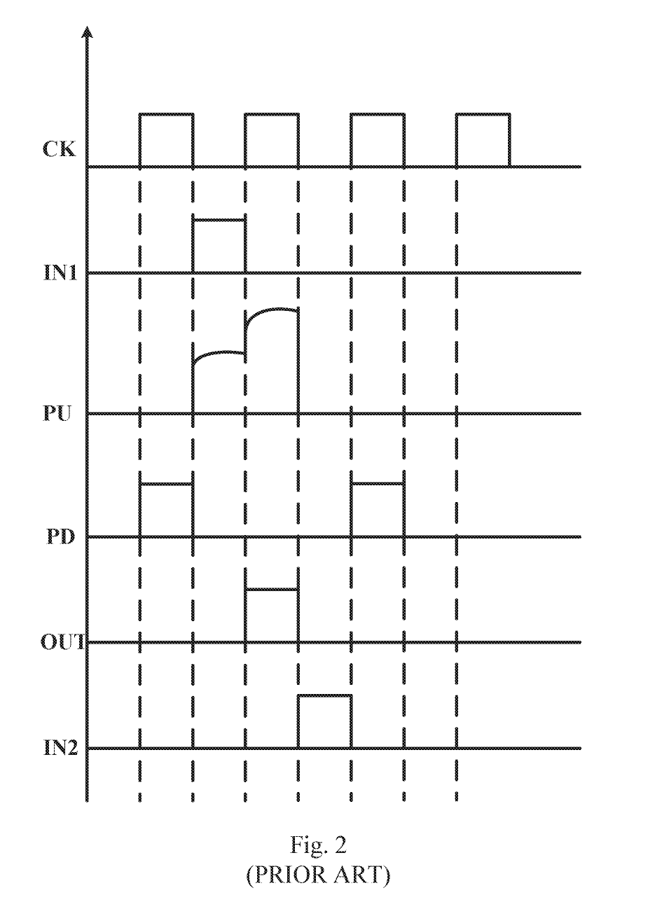

A common shift register unit structure in the prior art is shown in FIG. 1, and FIG. 2 is a timing diagram of several key signals when the shift register unit in FIG. 1 drives. Nine switching transistors M1-M9 and a storage capacitor C1 are included in the shift register. The process of driving the shift register unit in FIG. 1 may be specifically as follows.

In a first stage, a low electrical level is input at the input signal terminal IN1 and restore signal IN2, so that the transistors M1, M2, M4 are turned off, while at the time PU is a low potential so that the transistor M3 is turned off, and Output at the input terminal is at a low potential so that M6, M7 are turned off. When the clock signal CK is at a high electrical level, M5, M8 are turned on, while at the time the potential of PD is high such that M9 is turned on to remove the noise on the Output terminal.

In a second stage, a high electrical level is input at the input signal terminal IN1 so that the transistor M1 is turned on, a pull-up node PU is at a high potential, the capacitor C1 is pre-charged, and the transistor M3 is turned on, while at this time the CK signal is at a low electrical level.

In a third stage, a low electrical level is input at the input signal terminal IN2; when the clock input terminal CK is at a high electrical level, M1 is turned off, the potential at the point PU remains at a high electrical level, and M3′ is turned on; when CLK1 is at a high electrical level, Output outputs a high electrical level, and at the time M7, M6 are turned on while M5 is turned off so that the PD potential at this time is at a low electrical level, M9 is turned off, ensuring that the signal may be stable outputted.

In a fourth stage, a low electrical level is input at the input signal terminal IN1 and CK, and a high electrical level is applied at the input signal terminal. At the time, M2, M4 are turned on to discharge the capacitor C1 and the output terminal Output, so that the potential of the point PU and Output are at a low electrical level.

Before the arrival of the next frame, the gate shift register consistently repeat the fourth stage and the first stage.

It can be seen through the above analysis that, when the point PU and CK are at a high electrical level, M8 is turned on so that M5 is turned off and M6 is turned on to make PD at a low potential, and M10 is turned off to provide normal outputs at Output. That is, when the point PU and CK are high at the same time, four TFT M5, M6, M7, M8 are used to rest the point PD to a low potential, wherein four TFT M5, M6, M7, M8 constitute the reset reinforce control module. Such a reset reinforce control module takes up more area in border regions and is not conducive to narrowing borders of the display device.

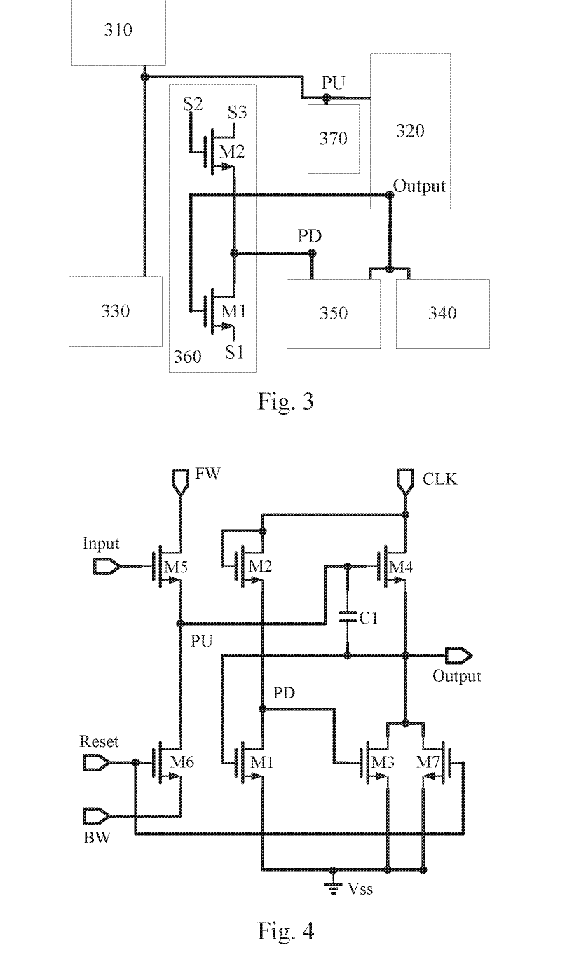

A shift register unit, according to one embodiment, is shown in FIG. 3.

The shift register unit includes an input module 310, an output module 320, a restoration module 330, a reset module 340, a reset reinforce module 350 and a reset reinforce control module 360 and an energy storage module 370.

All of the input module 310, the output module 320, the restoration module 330 and the energy storage module 370 are connected to a first node PU. The output module 320 includes an output terminal OUT adapted to output a shift signal at a first electrical level via the output terminal OUT when the voltage at the first node PU is at the first electrical level.

The reset module 340 is connected to the output terminal OUT of the output module 320, and is adapted to set the voltage at the output terminal OUT of the output module 320 to a second electrical level.

Both the reset reinforce module 350 and the reset reinforce control module 360 are connected to a second node PD, the reset reinforce module 350 is adapted to set the voltage at the output terminal OUT of the output module 320 to the second electrical level when the second node PD reaches a start electrical level of the reset reinforce module 350, and the second electrical level is opposite to the first electrical level.

The reset reinforce control module 360 includes a first transistor M1 and a second transistor M2, the channel width to length ratio of the first transistor M1 is greater than the channel width to length ratio of the second transistor M2, and by controlling switch states of the first transistor M1 and of the second transistor M2, the voltage at the second node PD can be controlled.

A method of driving the shift register unit shown in FIG. 3 is described below.

When the output module 320 outputs a shift pulse at the first electrical level, switch states of the first transistor M1 and of the second transistor M2 are controlled so that the voltage at the second node PD does not reach the start electrical level of the reset reinforce module 350.

After the reset module 340 sets the voltage at the output terminal of the output module 320 to the second electrical level, switch states of the first transistor M1 and of the second transistor M2 are controlled so that the voltage at the second node PD reaches the start electrical level of the reset reinforce module 350.

In the shift register unit and the driving method thereof described herein, when the shift register unit outputs a pulse level, by controlling the switching states of the first transistor M1 and of the second transistor M2, the voltage at the second node PD does not reach the start electrical level of the reset reinforce module 350, so that the reset reinforce module 350 will not be started and accordingly the output module 320 will not be affected in outputting a shift pulse. After the output terminal of the output module 320 is set by the reset module 340 to a second electrical level (after the completion of output of a shift pulse), the switching states of the first transistor M1 and of the second transistor M2 are controlled so that the voltage at the second node PD reaches the start electrical level of the reset reinforce module 350, making the reset reinforce module 350 to conduct a reinforce reset on the voltage at the output terminal of the output module 320. Thus two transistors M1 and M2 achieve the function of the reset reinforce control. Compared to typical shift register units, it can reduce the use of transistors, thereby being able to occupy less area of the border region and helping narrow borders of the display device.

According to an exemplary embodiment and referring to FIG. 3, the reset reinforce control module 360 herein also has a first input terminal S1, a second input terminal S2 and a third input terminal S3, wherein the first transistor M1 has its gate connected to the output terminal of the output module, its source connected to the second node PD and its drain connected to the first input terminal S1, and is turned on when the output terminal of the output module 320 is at the first electrical level. The second transistor M2 has its drain connected to the second node PD, its gate connected to the second input terminal S2, and its source connected to the third input terminal S3. The channel width to length ratio of the first transistor M1 is greater than the channel width to length ratio of the second transistor M2.

At the time, in the drive method, when the output module 320 outputs a shift pulse at the first electrical level, controlling switch states of the first transistor M1 and of the second transistor M2 so that the voltage at the second node PD does not reach the start electrical level of the reset reinforce module 350 includes the following.

Voltage is applied at the first input terminal S1 that turns the reset reinforce module 350 off when the output module 320 outputs a shift pulse at the first electrical level.

After the reset module 340 sets the voltage at the output terminal of the output module 320 to the second electrical level, controlling switch states of the first transistor M1 and of the second transistor M2 so that the voltage at the second node PD reaches the start electrical level of the reset reinforce module 350 includes the following.

After the reset module 340 sets the voltage at the output terminal OUT of the output module 320 to the second electrical level, a signal is applied at the second input terminal S2 that turns the second transistor M2 on and voltage is applied at the third input terminal S3 that starts the reset reinforce module 350.

Thus, when the output module 320 outputs a shift pulse at the first electrical level, the first transistor M1 is turned on, and at the time by applying voltage at the first input terminal that turns the reset reinforce module 350 off, voltage of the second node can be maintained at the voltage that can turn the reset reinforce module 350 off, while the reset reinforce module 350 will not be started and accordingly the output module 350 will not be affected in outputting the shift pulse. After the output terminal of the output module 320 is set by the reset module 340 to the second electrical level (after the completion of output of the shift pulse), the first transistor M1 is turned off, the second transistor M2 is turned on by applying a signal at the second input terminal S2, and applying at the third input terminal S3 voltage that can start the reset reinforce module 350, so that the reset reinforce module 350 conducts reinforce reset on the voltage at the output terminal of the output module 320.

It should be understood that the connection between the first transistor M1 and the second transistor M2 is not necessarily as shown in FIG. 3 , the skilled in the art may use other specific connections between the first transistor M1 and the second transistor M2 in the reset reinforce control module 360 without affecting the implementation of the present disclosure.

According to exemplary embodiments, the second input terminal S2 and the third input terminal S3 may be the same input terminal, and the start electrical level of the reset reinforce module 350 is the same as the start electrical level of the second transistor M2.

According to exemplary embodiments, by inputting, at the second input terminal S2 and the third input terminal S3, voltage that can enable the second transistor M2, the second transistor M2 can be started, so that the second node PD is also set to the corresponding voltage that can start the second transistor M2 and reset reinforce module 350, so that the reset reinforce module 350 can also be started. Thus, in the corresponding gate drive circuit, one signal line may be reduced, whereby the area of the border region occupied by the corresponding gate drive circuit can be further reduced.

According to exemplary embodiments, the reset reinforce module 350 abovementioned may include a third transistor M3 (not shown), the third transistor M3 having its source connected to the output terminal Output of the output module 320, its gate connected to the second node PD and its source connected to the first input terminal S1; the start electrical level of the third transistor M3 is the first electrical level.

Since the drain of the third transistor M3 is connected to the first input terminal and the start electrical level of the third transistor M3 is the first electrical level, the electrical level of the second node PD can be maintained at the second electrical level in the stage of outputting a shift pulse (at the time the first transistor M1 is turned on) by inputting a constant second electrical level at the first input terminal S1, while after outputting a shift pulse so that output stage (the first transistor M1 is turned off, the third transistor M3 starts), the electrical level of the output terminal Output is set to the second electrical level, so that on the one hand the difficulty in controlling the shift register unit is reduced. On the other hand, separately connecting the drain of the third transistor M3 also to a signal line can be avoided, and likewise the corresponding area of the border region occupied by the gate drive circuit can be further reduced.

In further embodiments, the output module 320 includes a fourth transistor M4 (not shown), the fourth transistor M4 having its source connected to the third input terminal S3, its drain connected to the output terminal Output of the output module 320 and its gate connected to the first node PU; the start electrical level of the fourth transistor M4 is at the first electrical level.

Here the fourth transistor M4 and the drain of the second transistor M2 are connected to the same input terminal S3. Since in general applications, the input terminal S3 of the output module 320 will access the clock signals, then in the following process, the clock signals will form multiple starts of the second transistor M2. Correspondingly, the reset reinforce module 350 is started multiple times too, forming multiple resets at the Output end, so as to avoid charge accumulation at the Output end, and improve the reset effect.

According to exemplary embodiments, the input module 310 is adapted to set the voltage of the first node PU to the first voltage level. The input module 310 may include a fifth transistor M5 (not shown) and has a fourth input terminal and a fifth input terminal. The fifth transistor M5 having its source connected to the fourth input terminal, its gate connected to the fifth input terminal and its drain connected to the first node PU. By turning the transistor M5 on and applying voltage of the first electrical level at the fourth input terminal connected to the source, voltage at the first node PU is set to the first electrical level.

The restoration module 330 is adapted to reset the voltage of the first node PU to the second electrical level, and includes a sixth transistor M6 (not shown in the drawings) and having a sixth input terminal and a seventh input terminal. The sixth transistor M6 having its source connected to the first node PU, its gate connected to the seventh input terminal and its drain connected to the sixth input terminal. By turning the transistor M6 on and applying voltage of the first electrical level at the sixth input terminal connected to the drain, voltage at the first node PU is set to the first electrical level.

Both the start electrical levels of the fifth transistor M5 and of the sixth transistor M6 are the first electrical level.

This may enable the corresponding shift register unit to implement forward scanning and reverse scanning. For example, in specific implementations, when forward scanning is needed, the first electrical level is inputted at the fourth input terminal, the second electrical level is inputted at the sixth input terminal, the shift signal is inputted to the fifth input terminal, and the restoration signal is inputted to the seventh input terminal; when reverse scanning is needed, the second electrical level is inputted to the fourth input terminal, the first electrical level is inputted at the sixth input terminal, the shift signal is inputted to the seventh input terminal, and the restoration signal is inputted to the fifth input terminal.

If bidirectional scanning is not needed, the structure of the aforementioned shift register unit may be improved so that the gate and source of the fifth transistor M5 are connected to the same input terminal and/or the drain of the transistor M6 may be connected to the first input terminal S1, thereby reducing the use of signal lines.

In some embodiments, the reset module 340 may include a seventh transistor M7 (not shown), the seventh transistor M7 having its gate connected to the seventh input terminal, its source connected to the output terminal Output of the output module 320 and its drain connected to the first input terminal S1; the start electrical level of the seventh transistor M7 is at the first electrical level. The first input terminal S1 and the seventh input terminal are multiplexed, thereby reducing the use of signal lines likewise.

In specific implementations, the abovementioned energy storage module 370 may be a capacitor C1 (not shown), the capacitor having a first terminal connected to the first node PU, and a second terminal connected to the output terminal Output of the output module 320.

In specific implementations, each of the transistors is N-type transistor. At the time the first electrical level is high and the second electrical level is low. In this regard the production process may be unified, thereby reducing production difficulty. It should be understood that part of the transistors abovementioned can be replaced with P-type transistors.

In specific implementations, the width to length ratio of the first transistor M1 is 4-6 times, preferably 5 times, the width to length ratio of the second transistor M2.

The shift register unit provided according to the embodiments described herein is exemplarily described below in combination with a specific circuit structure. With reference to FIG. 4, the shift register unit includes seven N-type switching transistors M1-M7 and a capacitor C1, and has a plurality of input terminals CLK, FW, Input, Reset, BW, Vss. The gate of the first transistor M1 is connected to the drain of the fourth transistor M4, and both are connected to the shift signal output terminal Output. The source of the M1 is connected to the second node PD, and the drain is connected to the input terminal Vss. The second transistor M2 has its drain connected to the second node PD, its gate and source connected to the input terminal CLK, the channel width to length ratio of the first transistor M1 being larger than the channel width to length ratio of the second transistor M2. The third transistor M3 has its source connected to the shift signal output terminal Output, its gate connected to the second node PD and its drain connected to the input terminal Vss. The fourth transistor M4 has its source connected the input terminal CLK, its gate connected to the first node PU and its drain connected to the shift signal output terminal Output. The fifth transistor M5 has its source connected to the input terminal FW, its gate connected to the input terminal Input, and its drain connected to the first node PU the sixth transistor M6 has its source connected to the first node PU, its gate connected to the input terminal Reset, and its drain connected to the input terminal BW. The seventh transistor M7 has its source connected to the shift signal output terminal Output, its gate connected to the input terminal Reset, and its drain connected to the input terminal Vss. The capacitor C1 has one end connect to the first node PU, and the other end connected to the output terminal Output.

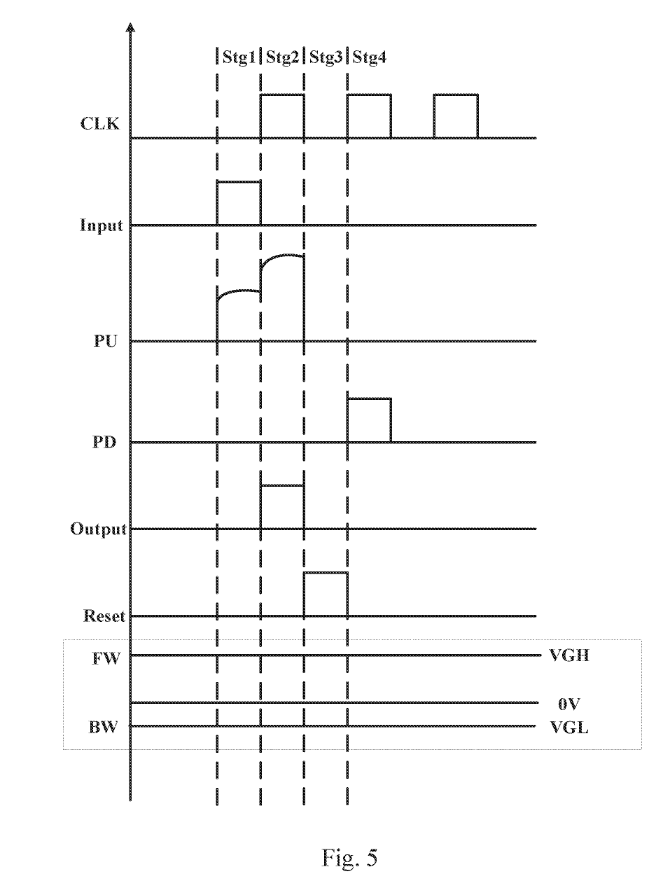

The shift register unit abovementioned may implement the bidirectional scanning, and the process of forward scanning will be described specifically below in combination with FIG. 5. As shown in FIG. 5, the drive process in the shift register unit within each frame may be divided into four stages.

The first stage Stg1 is shift signal input stage, in which a shift pulse signal at a high electrical level is applied at the input terminal Input, a low electrical level is applied at the input terminal Reset, a high electrical level is applied at the input terminal CLK, a high electrical level VGH is applied at the input terminal FW, a low electrical level VGL is applied at the input terminal BW, and a low electrical level is applied at the input terminal Vss. Because of the presence of capacitor C1, the voltage of the first node PU is maintained at a high electrical level. At the time, the transistor M4 is turned on continually and the output terminal Output outputs a high electrical level that is the shift signal to be outputted. Since the output terminal Output is at a high electrical level, and the input terminal CLK is also at a high electrical level, then both transistor M1 and transistor M2 are turned on; since the width to length ratio of the transistor M1 is larger than the width to length ratio of the transistor M2, at the time the voltage at the second node PD is the same as the input terminal Vss and both are at a low electrical level. Thus, M3 will not be turned on, preventing the decrease in voltage of the output terminal Output from affecting the output of the shift pulse. Since the input terminal Reset is still at a low electrical level, both transistor M6 and transistor M7 are turned off, preventing from affecting the output. Till now, the output of the shift pulse signal is completed.

The first stage Stg1 is a shift signal input stage, in which a shift pulse signal at a high electrical level is applied at the input terminal Input, a low electrical level is applied at the input terminal Reset, a high electrical level is applied at the input terminal CLK, a high electrical level VGH is applied at the input terminal FW, a low electrical level VGL is applied at the input terminal BW, and a low electrical level is applied at the input terminal Vss. At the time transistor M5 is turned on so that the first node PU is set at a high electrical level and transistor M4 is correspondingly turned on. All other transistors are turned off. Since the input terminal applies a low electrical level at CLK, at the time both the output terminal Output and the input terminal CLK are at a low electrical level. At this stage the pulse signal will not be outputted.

The second stage Stg2 is a shift signal output stage, in which a low electrical level is applied at the input terminal Input, a low electrical level is applied at the input terminal Reset, a high electrical level is applied at the input terminal CLK, a high electrical level VGH is applied at the input terminal FW, a low electrical level VGL is applied at the input terminal BW, and a low electrical level Vss is applied at the input terminal. Because of the presence of the capacitor C1, voltage at the first node PU will be maintained at a high electrical level. At this point transistor M4 will be turned on continually, the output terminal Output outputs a high electrical level, and the high electrical level is the shift signal to be outputted. Since the output terminal Output is at a high electrical level and the input terminal CLK is also at a high electrical level, then both transistors M1 and transistor M2 will be turned on. Since the width to length ratio of the transistor M1 is greater than the width to length ratio of the transistor M2, voltage at the second node PD at this time is the same as the input terminal Vss and both are at a low electrical level. Thus, transistor M3 will not be turned on, to prevent the decrease in voltage at the output terminal Output from affecting the output of the shift pulse. Since the input terminal Reset is still at a low electrical level, both transistors M6 and M7 will be turned off, to avoid affecting the output thereof. Till now, the output of the shift pulse signal is completed.

The third stage stg3 is a reset and restoration stage, in which a low electrical level is applied at the input terminal Input, a high electrical level is applied at the input terminal Reset, a low electrical level is applied at the input terminal CLK, a high electrical level VGH is applied at the input terminal FW, a low electrical level VGL is applied at the input terminal BW, and a low electrical level is applied at the input terminal Vss. At the time transistors M6 and M7 are turned on, and reset the voltages on both ends of the capacitor C1 to a low electrical level, respectively.

The fourth stage Stg4 is a reset reinforce stage, and all the time after the third stage within one frame can be considered the fourth stage, in which a constant low electrical level is applied at the input terminal Input, a constant low electrical level is applied at the input terminal Reset, a constant high level VGH is applied at the input terminal FW, a constant low electrical level VGL is applied at the input terminal BW, and a constant low electrical level is applied at the input terminal Vss. At this time, the transistors M5, M6, and M7 are turned off, and since the output terminal Output and the first node PU are at a low electrical level, transistors M1 and M4 are turned off too. A clock signal may be applied at the input terminal CLK, and each time the clock signal is at a high electrical level, the transistor M2 is turned on to set the electrical level at the second node PD to a high electrical level, so that the transistor M3 is turned on to complete one reset of the output terminal Output, so that at the fourth stage Stg4 multiple resets of the output terminal Output can be achieved.

It may be appreciated that, in the abovementioned driving process, the transistor M7 and the input terminal Reset connected thereto reset the voltage at the output terminal Output, and constitute a reset module. The input terminal Vss corresponds to the first input terminal S1. The transistor M3 functions to conduct multiple reinforce restorations on the output terminal Output after the transistor M7 conducts one restoration on the output terminal Output, and constitutes a reset reinforce module. Transistors M1 and M2 and the input terminal connected thereto function to control the switching of transistor M3, and constitute a reset reinforce control module. Wherein the input terminal CLK corresponds to the second input terminal S2 and the third input terminal S3 (the second input terminal S2 and the third input terminal S3 are the same input terminal) abovementioned. The transistor M5 and the input terminal FW connected thereto (corresponding to the fourth input terminal abovementioned), the Input (corresponding to the fifth input terminal abovementioned) terminal complete the process of input of the shift signal, and constitute an input module. Transistor M4 completes the process of output of the shift signal, and constitutes an output module. Transistor M6 and the input terminal Reset connected thereto (corresponding to the seventh input terminal abovementioned), BW (corresponding to the sixth input terminal abovementioned) then complete the process of restoration of the first node PU, and constitute a restoration module.

In the embodiments described above, the electrical level applied at the input terminal CLK constitutes a clock signal on the whole, and the signals applied at the input terminal Input and Reset each contain a pulse signal at a high electrical level, and compared with the high electrical level pulse applied at the output terminal Output, the high electrical level pulse of the signal applied at the input terminal Reset is shifted one clock, so that the shift signal outputted by next level of shift register unit signal may be used as a restoration signal of this level of shift register unit to be inputted to the restoration terminal.

During reverse scanning, a high electrical level VGH is applied at the BW, a low electrical level VGL is applied at the FW.

As can be seen, compared with typical shift register units, the shift register unit shown in FIG. 4 reduces the use of two transistors, then the gate drive circuit including the shift register unit in FIG. 4 can use less area of the border region thereby narrowing the display device, and the shift register unit in FIG. 4 can implement bidirectional scanning.

The embodiments described herein also provide a gate drive circuit including a plurality of cascaded shift register units, the shift register units being shift register units of any of the preceding. It may be appreciated that in specific implementations, among the respective shift register units abovementioned, in any level of shift register unit except for the last level and the first level, the input module is connected to the output module of the upper level of the shift register unit to receive the shift signal outputted by the upper level of shift register unit, while the output module is connected to the input module of the lower level of shift register unit to output the shift register signal to the lower level of shift register unit, and the output terminal of the output module is also connected to the restoration module of the upper level of shift register unit to restore the upper level of shift register unit. The input terminal of the first level of shift register unit is connected to a start signal.

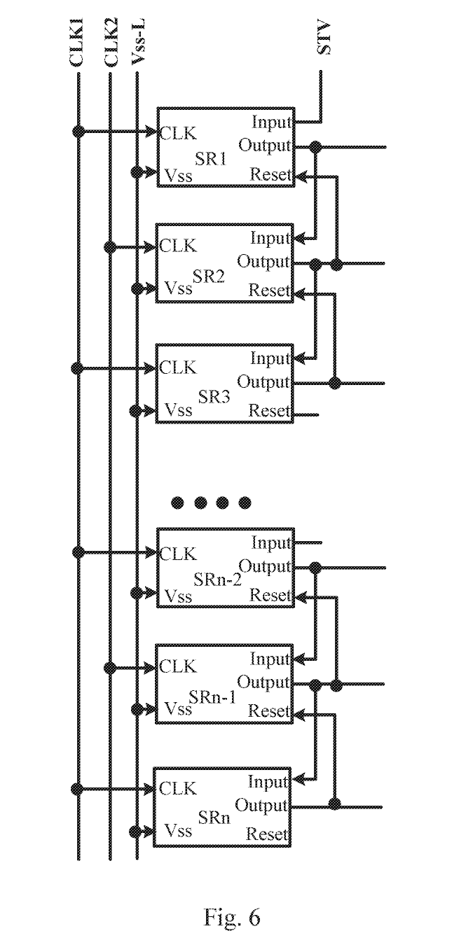

For the shift register unit according to the embodiments shown in FIG. 4, the case of the cascaded gate drive circuit provided in the present disclosure may refer to FIG. 6, the input terminal Input of the first level of shift register unit SR1 is connected to a start signal line STV, all the input terminals Input of other shift register units SR2, SR3, SRn-2, SRn-1 except the first level of shift register unit SR1, are connected to the output terminal Output of the upper level of shift register unit, and all the input terminals Reset are connected to the input terminal Input of the lower level of shift register unit input. Accordingly, all the output terminals Output of other shift register units except for the last level of shift register unit SRn are connected to the input terminal Input of the lower level of shift register unit and to the input terminal Reset of the upper level of shift register unit. FIG. 6 shows the case where the odd-numbered levels of shift register units and the even-numbered levels of shift register units are connected to different clock signal lines CLK1 and CLK2, respectively, the respective input terminals Vss being connected to the signal line Vss-L. In addition to the signal lines shown in the figure, the gate drive circuit in FIG. 6 also generally provides voltage to the input terminal FW and input terminal BW. Since voltages on these input terminals are relatively constant, they may be connected to the common electrodes throughout the entire substrate (not shown).

In further embodiments, a display device includes the gate drive circuit of any one of the preceding embodiments.

Here the display device may be, for example: electronic paper, mobile phones, tablet computers, televisions, displays, notebook computers, digital picture frames, navigation systems and any other products or components having a display function.

The above are only example embodiments to carry out the present disclosure, but the scope of the present disclosure is not limited thereto. Variations or substitutions easily conceivable to those skilled in the art within the technical scope of the present disclosure also should fall within the scope of the present disclosure.

1. A shift register unit comprising:
an input module, an output module, a restoration module, a reset module, a reset reinforce module, a reset reinforce control module, and an energy storage module;
wherein, the input module, the output module, the restoration module and the energy storage module are connected to a first node;
wherein, the output module comprises an output terminal adapted to output a shift signal at a first electrical level when the voltage at the first node is at the first electrical level;
wherein, the reset module is connected to the output terminal of the output module, and the reset module is adapted to set the voltage at the output terminal of the output module to a second electrical level;
wherein, both the reset reinforce module and the reset reinforce control module are connected to a second node, and the reset reinforce control module comprises a first transistor and a second transistor, a channel width to length ratio of the first transistor is greater than a channel width to length ratio of the second transistor;
wherein, by controlling switch states of the first transistor and the second transistor, the voltage at the second node is controlled; and
wherein, the reset reinforce module is adapted to set the voltage at the output terminal of the output module to the second electrical level when the voltage at the second node reaches a start electrical level of the reset reinforce module, and the second electrical level is opposite to the first electrical level.

2. The shift register unit according to claim 1, wherein the reset reinforce control module includes a first input terminal, a second input terminal and a third input terminal, wherein the first transistor has a gate connected to the output terminal of the output module, a source connected to the second node and a drain connected to the first input terminal, wherein the first transistor is turned on when the output terminal of the output module is at the first electrical level, and wherein the second transistor has a drain connected to the second node, a gate connected to the second input terminal, and a source connected to the third input terminal.

3. The shift register unit according to claim 2, wherein the second input terminal and the third input terminal are the same input terminal, and the start electrical level of the reset reinforce module is the same as a start electrical level of the second transistor.

4. The shift register unit according to claim 2, wherein the reset reinforce module comprises a third transistor, and the third transistor has a source connected to the output terminal of the output module, a gate connected to the second node and a drain connected to the first input terminal, and wherein a start electrical level of the third transistor is the same as the first electrical level.

5. The shift register unit according to claim 2, wherein the output module comprises a fourth transistor, and the fourth transistor has a source connected to the third input terminal, a drain connected to the output terminal of the output module and a gate connected to the first node, and wherein a start electrical level of the fourth transistor is the same as the first electrical level.

6. The shift register unit according to claim 1, wherein the input module comprises a fifth transistor and has a fourth input terminal and a fifth input terminal, and the fifth transistor has a source connected to the fourth input terminal, a gate connected to the fifth input terminal and a drain connected to the first node;
wherein the restoration module comprises a sixth transistor and has a sixth input terminal and a seventh input terminal, and the sixth transistor has a source connected to the first node, a gate connected to the seventh input terminal and a drain connected to the sixth input terminal; and
wherein, both a start electrical level of the fifth transistor and a start electrical level of the sixth transistor are the same as the first electrical level.

7. The shift register unit according to claim 6, wherein the reset module comprises a seventh transistor, and the seventh transistor has a gate connected to the seventh input terminal, a source connected to the output terminal of the output module and a drain connected to the first input terminal, and wherein a start electrical level of the seventh transistor is the same as the first electrical level.

8. The shift register unit according to claim 7, wherein the first transistor, second transistor, third transistor, fourth transistor, fifth transistor, sixth transistor, and seventh transistor are N-type transistors.

9. The shift register unit according to claim 1, wherein the energy storage module is a capacitor and the capacitor has a first terminal connected to the first node and a second terminal connected to the output terminal of the output module.

10. The shift register unit according to claim 1, wherein a width to length ratio of the first transistor is between and inclusive of four to six times a width to length ratio of the second transistor.

11. A gate drive circuit comprising more than one of the cascaded shift register unit according to claim 1.

12. A gate drive circuit comprising more than one of the cascaded shift register unit according to claim 2.

13. A gate drive circuit comprising more than one of the cascaded shift register unit according to claim 3.

14. A gate drive circuit comprising more than one of the cascaded shift register unit according to claim 10.

15. A method of driving the shift register unit of claim 1 comprising:
controlling, in response to a shift pulse output at the first electrical level by the output module, switch states of the first transistor and of the second transistor so that the voltage at the second node does not reach the start electrical level of the reset reinforce module;
controlling, in response to the voltage at the output terminal of the output module being set to the second electrical level by the reset module, switch states of the first transistor and of the second transistor so that the voltage at the second node reaches the start electrical level of the reset reinforce module.

16. The method according to claim 15, wherein the reset reinforce control module of the shift register unit has a first input terminal, a second input terminal and a third input terminal, wherein the first transistor has a gate connected to the output terminal of the output module, a source connected to the second node and a drain connected to the first input terminal, wherein the first transistor is turned on when the output terminal of the output module is at the first electrical level, wherein the second transistor has a drain connected to the second node, a gate connected to the second input terminal, and a source connected to the third input terminal, and wherein controlling switch states of the first transistor and of the second transistor so that the voltage at the second node does not reach the start electrical level of the reset reinforce module comprises applying voltage at the first input terminal that turns the reset reinforce module off

17. The method according to claim 15, wherein the reset reinforce control module of the shift register unit has a first input terminal, a second input terminal and a third input terminal, wherein the first transistor has a gate connected to the output terminal of the output module, a source connected to the second node and a drain connected to the first input terminal, and the first transistor is turned on when the output terminal of the output module is at the first electrical level, wherein the second transistor has a drain connected to the second node, a gate connected to the second input terminal, and a source connected to the third input terminal, and wherein controlling switch states of the first transistor and of the second transistor so that the voltage at the second node reaches the start electrical level of the reset reinforce module comprises applying a signal at the second input terminal to turn the second transistor on and applying voltage at the third input terminal that starts the reset reinforce module.

18. A display device comprising the gate drive circuit according to claim 11.

19. A display device comprising the gate drive circuit according to claim 12.

20. A display device comprising the gate drive circuit according to claim 13.
